(19) United States
(12) Patent Application Publication
(10) Pub. No.: US 2012/0149195 A1
(43) Pub. Date: Jun. 14, 2012

(54) METHOD FOR MANUFACTURING INTEGRATED CIRCUIT DEVICE

(75) Inventor: Takuji KUNIYA, Mie-ken (JP)

(73) Assignee: Kabushiki Kaisha Toshiba, Tokyo (JP)

(21) Appl. No.: 13/217,439

(22) Filed: Aug. 25, 2011

(30) Foreign Application Priority Data
Dec. 9, 2010 (JP) 2010-274308

(51) Int. Cl. H01L 21/283

(52) U.S. Cl. 438/685; 257/E21.159

(57) ABSTRACT

According to one embodiment, a method for manufacturing an integrated circuit device, includes etching a metal member using a gas including a halogen, forming a silicon oxide film so as to cover an etching face of the etched metal member without exposing the metal member to atmospheric air, and removing the silicon oxide film.

### CROSS-REFERENCE TO RELATED APPLICATIONS

This application is based upon and claims the benefit of priority from the prior Japanese Patent Application No. 2010-274308, filed on Dec. 9, 2010; the entire contents of which are incorporated herein by reference.

### FIELD

Embodiments described herein relate generally to a method for a manufacturing an integrated circuit device.

### BACKGROUND

Conventionally, when integrated circuit devices are manufactured, it is common to form a metal film on a substrate, and then dry etch the metal film using a halogen gas to process the arrangement to a desired form. For example, in the case of manufacturing Resistance Random Access Memory (ReRAM) that is a three-dimensional memory device, a process of forming a stacked body by subsequently depositing a metal film and a silicon film, and a process of processing the stacked body to form pillars by dry etching using a halogen gas are performed repeatedly.

When dry etching with a halogen gas is performed, the halogen element is absorbed by the process material, reacts with the elements forming the process material and the like, and thus a halogen element remains on the etching surface. Then, when the process material is exposed to the atmospheric air with the halogen element still present, the halogen element reacts with moisture in the air, corroding the metal members. Hence, it is necessary to remove the residual halogen element before exposing the process material to atmospheric air. Conventionally, the halogen element has been removed by exposing the process material to oxygen (O₂) discharge or discharge with a mixed gas of nitrogen and hydrogen (N₂/H₂) while heating the process material. However, when discharge processing of this type is performed, the metal film is oxidized or nitrided, degrading characteristics of the metal film. For example, in the case of the metal film has been processed to form interconnects or electrodes, the electrical resistance of the interconnects or electrodes is increased.

### BRIEF DESCRIPTION OF THE DRAWINGS

FIGS. 1 to 6 are cross-sectional process views illustrating a method for manufacturing an integrated circuit device according to an embodiment.

### DETAILED DESCRIPTION

In general, according to one embodiment, a method for manufacturing an integrated circuit device, includes etching a metal member using a gas including a halogen, forming a silicon oxide film so as to cover an etching face of the etched metal member without exposing the metal member to atmospheric air, and removing the silicon oxide film.

Hereinafter, an embodiment of the invention will be explained below with reference to the drawings.

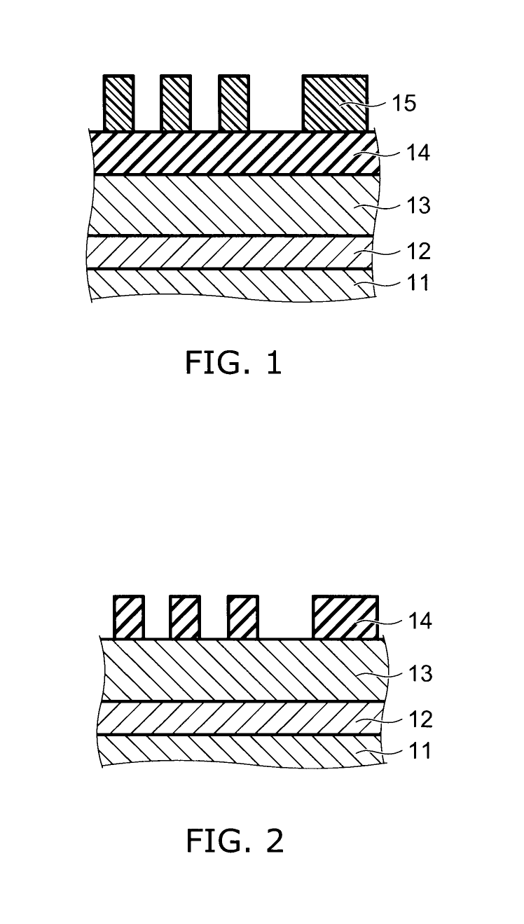

FIGS. 1 to 6 are cross-sectional process views illustrating a method for manufacturing an integrated circuit device according to the embodiment.

The type of the integrated circuit device to be manufactured in the embodiment is not limited, but may be a ReRAM, for example.

First, as illustrated in FIG. 1, a polysilicon film 12 is formed on a substrate film 11. The substrate film 11 may, for example, be a silicon substrate, a conductive film, a semiconductor film, or an insulating film. The polysilicon film 12 is formed by depositing silicon (Si) using, for example, a Chemical Vapor Deposition (CVD) method. Next, a metal film 13 of tungsten (W), titanium (Ti) or the like is formed on the polysilicon film 12 by, for example, a CVD method or Physical Vapor Deposition (PVD) method.

Next, a hard mask film 14 is formed on the metal film 13 by depositing silicon oxide using, for example, a CVD method with Tetra Ethyl Ortho Silicate (TEOS) as a source material. In this way, a stacked film having the polysilicon film 12, the metal film 13, and the hard mask film 14 subsequently stacked is formed on the substrate film 11. Next, a resist film is applied on the hard mask film 14, and a resist pattern 15 is formed by patterning using a lithographic method on the resist film.

Next, as illustrated in FIG. 2, the hard mask film 14 is selectively removed by performing anisotropic etching with the resist pattern 15 (see FIG. 1) as a mask. As a result, the pattern of the resist pattern 15 is transferred to the hard mask film 14. Thereafter, oxygen (O₂) discharge or the like is performed to remove the resist pattern 15.

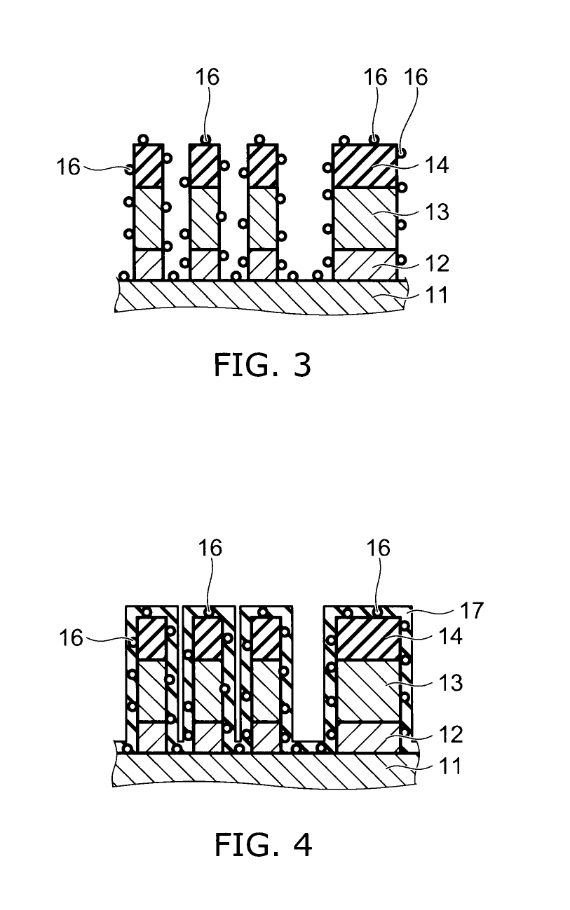

Next, as illustrated in FIG. 3, the process material having the polysilicon film 12, the metal film 13 and the hard mask film 14 stacked on the substrate film 11 is introduced into a process chamber (not illustrated). Then, with the hard mask film 14 as the mask, dry etching is performed using a gas including halogen, such as hydrogen bromide (HBr) or chlorine gas (Cl₂), as the etching gas. As a result, a process takes place whereby the metal film 13 and the polysilicon film 12 are selectively removed. At this time, a residue of the halogen element of bromine (Br), chlorine (Cl) or the like remains on the etching face of the process material due to absorption by the process material or reaction with the process material.

Hereinafter, the halogen element of this type will be referred to as “residual halogen”. In FIG. 3 and FIG. 4, for ease of illustration, the residual halogen is depicted schematically as white circles and labeled with the numeral “16”.

Next, the process material is moved from the process chamber to a film-forming chamber (not illustrated) by vacuum transfer. This movement is performed under a sustained vacuum.

Next, in the film-forming chamber, silicon oxide is deposited on the process material at room temperature using a CVD method with a mixed gas of silicon tetrachloride and oxygen (SiCl₄/O₂) or silicon tetrafluoride and oxygen (SiF₄/O₂) as the source material, as illustrated in FIG. 4. As a result, a silicon oxide film 17 is formed so as to cover etching faces of the process material. At this time, the residual halogen 16 is incorporated into the silicon oxide film 17. The composition of the silicon oxide film 17 can be expressed as SiOₓ. Here, the value x is preferably larger than 0 and smaller than 2 over the entire silicon oxide film 17, but locally may be 0, or 2 or larger. Since the value x over the entire silicon oxide film 17 is less than 2, it follows that the silicon oxide film 17 contains dangling bonds.

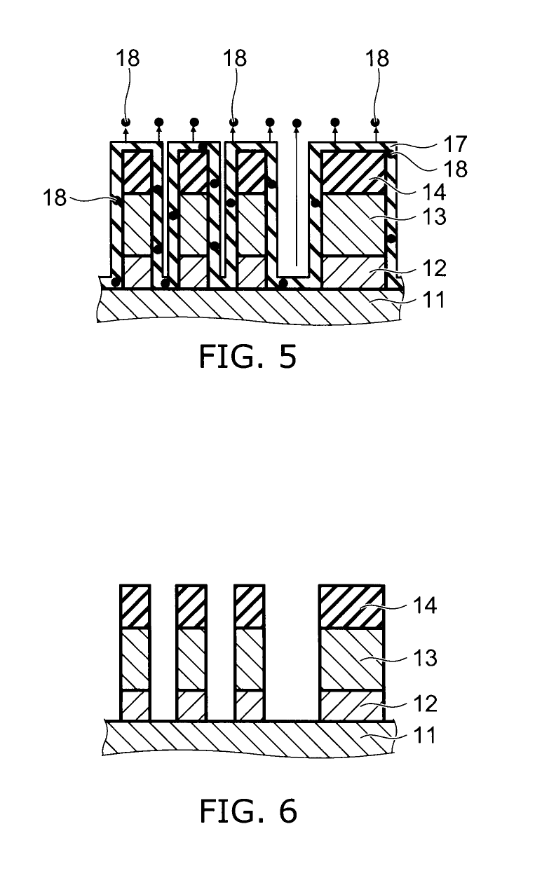

Hence, as illustrated in FIG. 5, the residual halogen 16 reacts with the silicon in the silicon oxide film 17 in a chemical reaction to form a halogen-silicon compound 18. The halogen-silicon compound 18 is, for example, silicon bromide (SiBr) or silicon chloride (SiCI).

### Si+Br→SiBr↑

### Si+Cl→SiCl↑

In FIG. 5, for ease of illustration, the halogen-silicon compound 18 is depicted schematically as black circles. Since the vapor pressure of the halogen-silicon compound 18 is low, a portion of the halogen-silicon compound sublimates and is discharged from the silicon oxide film 17. The residual portion of the halogen-silicon compound 18 is solidified in the silicon oxide film 17.

Next, as illustrated in FIG. 6, the process material is introduced into a wet processing apparatus (not illustrated), and wet processing is performed using, for example, hydrofluoric acid. Specifically, the silicon oxide film 17 (see FIG. 5) is removed by dissolving the silicon oxide film 17 in the hydrofluoric acid. At this time, the halogen-silicon compound 18 (see FIG. 5) contained in the silicon oxide film 17 is removed with the silicon oxide film 17. As a result, the residual halogen is removed. At this time, a portion or all of the hard mask film 14 may be removed. In this way, a structure provided with the patterned polysilicon film 12 and metal film 13 on the substrate film 11 is manufactured. Thereafter, the integrated circuit device is manufactured by performing the necessary processes. Note that if, for example, the embodiment is a ReRAM manufacturing method, the patterned polysilicon film 12 and the metal film 13 will form, respectively, the diodes and electrodes that constitute the ReRAM memory cells.

In the integrated circuit device manufactured according to the embodiment, the side faces (etching faces) of the patterned metal film 13 are substantially not oxidized or nitrided. Hence, there is no need to remove any oxide layer or nitride layer from the metal film 13 and, consequently, no step is formed at a boundary between side faces of the metal film 13 and side faces of the polysilicon film 12.

Next, the effect of the embodiment will be explained.

In the embodiment, the silicon oxide film 17 is formed so as to cover the etching faces of the process material in a process illustrated in FIG. 4. As a result, the residual halogen 16 is incorporated into the silicon oxide film 17 where it reacts with the silicon in the silicon oxide film 17 to form the halogen-silicon compound 18. Then, as illustrated in FIG. 5, a portion of the halogen-silicon compound 18 sublimates and is discharged with the remainder being solidified in the silicon oxide film 17. Further, in a process illustrated in FIG. 6, the silicon oxide film 17 is removed using hydrofluoric acid, thereby also removing the halogen-silicon compound 18 solidified in the silicon oxide film 17. Thus, the residual halogen 16 can be removed from the process material. Consequently, even if the process material is subsequently exposed to the atmosphere, the metal film 13 will not be corroded as a result of the residual halogen. Hence, the metal film 13 that forms the metal members will not be degraded.

Further, in the embodiment, neither oxygen (O₂) discharge nor mixed gas discharge with hydrogen and nitrogen (N₂/H₂) is performed at high temperature to remove the residual halogen. Hence, the oxidation or nitridation of the metal film 13 caused by such discharges does not occur and degradation of the metal film 13 is avoided. Note that while removal of the residual halogen using an alkaline aqueous solution might be considered, such a method would result in the metal film 13 being dissolved in the alkaline aqueous solution. In the embodiment, however, there is no risk of such an occurrence because an alkaline aqueous solution is not used.

Moreover, in the embodiment, the silicon oxide film 17 is removed by the process illustrated in FIG. 6. Hence, in subsequent processes and on completion of the integrated circuit device, the chemically unstable silicon oxide film 17 containing the silicon dangling bonds will never affect the polysilicon film 12, metal film 13, or the like. Consequently, degradation of the polysilicon film 12 and the metal film 13 and thus the occurrence of defects such as short circuits can be prevented, making it possible to manufacture integrated circuit devices of high reliability.

Moreover, in the embodiment, between the dry etching with a halogen gas illustrated in FIG. 3 and the forming of the silicon oxide film 17 illustrated in FIG. 4, the process material is moved by vacuum transfer from the process chamber to the film-forming chamber. Consequently, the process material is not exposed to the atmospheric air containing moisture or the like between the two processes, and the corrosion of the metal film 13 that would occur as a result of the residual halogen reacting with the moisture in the atmosphere can be suppressed.

Thus, when the integrated circuit device is manufactured according to the embodiment, there is neither corrosion of the metal film 13 due to the residual halogen, nor oxidation or nitridation of the metal film 13 as a result of any process to remove the residual halogen. Hence, the metal members formed by the process of dry etching the metal film 13 are never degraded. For example, in a case where the metal members form interconnects, electrodes, or the like, the resistance values of such elements will not increase. Consequently, the degree of freedom afforded to the design of the integrated circuit device is increased. Moreover, a level of integration of the integrated circuit device can be increased.

Note that although the embodiment described an example in which the silicon oxide film 17 was removed by wet etching with a hydrofluoric acid, the invention is not limited to such a method, and the silicon oxide film 17 may, for example, be removed by wet etching using a choline. Specifically, in the process to remove the silicon oxide film 17 illustrated in FIG. 6, the silicon oxide film 17 may be dissolved in the choline.

Further, although the embodiment described an example in which the dry etching process illustrated in FIG. 3 was performed in the process chamber and the forming process of the silicon oxide film 17 illustrated in FIG. 4 was performed in the film-forming chamber, the invention is not limited to such a method. Those processes can be performed in same chamber. For example, both the dry etching process and the forming process for the silicon oxide film may be performed sequentially in a single chamber without opening the chamber to atmospheric air. Note that the atmosphere between the two processes is not limited to being a vacuum. For example, an atmosphere of dry air with a lower moisture content than atmospheric air is acceptable.

Further, although the embodiment described an example in which the silicon oxide film 17 was formed by depositing silicon oxide in the process illustrated in FIG. 4, the invention is not limited to such a method. For example, the silicon oxide film 17 may be formed by covering the etching faces of the process material with a thin silicon film by thinly depositing silicon and subsequently oxidizing the silicon film by, for example, exposure to atmospheric air. In this case, the processes from the dry etching process illustrated in FIG. 3 to the process to cover the etching faces with the silicon film are performed without exposing the process material to atmospheric air.

Furthermore, although in the embodiment an example was described in which the integrated circuit device was a ReRAM, the invention is not limited to a method for manufacturing such a device. For example, the integrated circuit device may be a semiconductor device equipped with metal gates, such as a logic circuit device including Complementary Metal Oxide Semiconductor (CMOS), or a semiconductor memory device such as Dynamic Random Access Memory (DRAM) or NAND-type flash memory.

According to the above-described embodiment, a method for manufacturing an integrated circuit device can be realized in which degradation of metal members is suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing an integrated circuit device, the method comprising:
etching a metal member using a gas including a halogen;
forming a silicon oxide film so as to cover an etching face of the etched metal member without exposing the metal member to atmospheric air; and
removing the silicon oxide film.

2. The method according to claim 1, wherein the removing of the silicon oxide film includes dissolving the silicon oxide film in a hydrofluoric acid.

3. The method according to claim 1, wherein the removing of the silicon oxide film includes dissolving the silicon oxide film in a choline.

4. The method according to claim 1, wherein hydrogen bromide is used as the gas including the halogen.

5. The method according to claim 1, wherein chlorine is used as the gas including the halogen.

6. The method according to claim 1, wherein the metal member includes tungsten or titanium.

7. The method according to claim 1, wherein between the etching of the metal member and the forming of the silicon oxide film, the metal member is left to sit in a dry atmosphere.

8. The method according to claim 7, wherein the dry atmosphere is a vacuum.

9. The method according to claim 1, wherein the etching of the metal member is performed in a process chamber, a process material is moved from the process chamber to a film-forming chamber by vacuum transfer, and the forming of the silicon oxide film is performed in the film-forming chamber.

10. The method according to claim 1, wherein the etching of the metal member and the forming of the silicon oxide film are performed in same chamber.

11. The method according to claim 10, wherein the etching of the metal member and the forming of the silicon oxide film are performed in the chamber without opening the chamber to atmospheric air.

12. The method according to claim 1, wherein the forming of the silicon oxide film includes depositing silicon oxide using a chemical vapor deposition method.

13. The method according to claim 1, wherein the forming of the silicon oxide film includes:
forming a silicon film; and
oxidizing the silicon film.

14. The method according to claim 1, wherein in the forming of the silicon oxide film, a composition of the silicon oxide film is expressed as SiOₓ, the value x is larger than 0 and smaller than 2.

15. The method according to claim 14, wherein the forming of the silicon oxide film includes reacting the residual halogen with a silicon in the silicon oxide film to form a halogen-silicon compound.

16. The method according to claim 1, further comprising:
forming a silicon film above a substrate, the metal member being formed on the silicon film; and
etching the silicon film,
wherein in the forming of the silicon oxide film, the silicon oxide film is formed so as to cover an etching face of the silicon film.

17. The method according to claim 16, wherein in the etching of the silicon film, the silicon film is etching using a gas including a halogen.

18. The method according to claim 16, wherein in the etching of the silicon film, a step is not formed at a boundary between a side face of the metal member and a side face of the silicon film.

19. The method according to claim 1, wherein the method is a ReRAM manufacturing method.

20. The method according to claim 19, wherein the etched metal member becomes an electrode.
